(19) United States
(12) Patent Application Publication
(10) Pub. No.: US 2023/0040019 A1
(43) Pub. Date: Feb. 9, 2023

(54) SEMICONDUCTOR DEVICE AND METHOD OF MANUFACTURING THE SAME

(71) Applicant: FUJI ELECTRIC CO., LTD., Kawasaki-shi (JP)

(72) Inventor: Yuji IIZUKA, Matsumoto-city (JP)

(73) Assignee: FUJI ELECTRIC CO., LTD., Kawasaki-shi (JP)

(21) Appl. No.: 17/852,545

(22) Filed: Jun. 29, 2022

(30) Foreign Application Priority Data
Aug. 5, 2021 (JP) 2021-128976

(51) Int. Cl. H01L 23/373; H01L 23/00; H01L 21/48

(52) U.S. Cl. CPC H01L 23/3735; H01L 24/32; H01L 24/83; H01L 21/4807; H01L 2224/32225; H01L 2224/83203; H01L 2224/83224; H01L 2924/15153

(57) ABSTRACT

A method of manufacturing a semiconductor device, the method including: preparing an insulated circuit substrate including a conductive plate; partially fixing a plate-like bonding member onto the conductive plate so as to make a positioning of the bonding member in a horizontal direction; mounting a semiconductor chip on the bonding member; and heating and melting the bonding member so as to form a bonding layer for bonding the insulated circuit substrate and the semiconductor chip each other.

### CROSS-REFERENCE TO RELATED APPLICATION

This application claims benefit of priority under 35 USC 119 based on Japanese Patent Application No. 2021-128976 filed on Aug. 5, 2021, the entire contents of which are incorporated by reference herein.

### BACKGROUND

### 1. Field of the Invention

The present invention relates to a semiconductor device such as a power module, and also to a method of manufacturing the same.

### 2. Description of the Related Art

A power module has a configuration in which a power semiconductor chip such as an insulated gate bipolar transistor (IGBT) and a diode is packaged in an external case, for example. The elements in the power module are integrated as an internal assembly such that the semiconductor chip, an insulated circuit substrate, and a metal base are stacked to be integrated, and are bonded to the external case made from resin.

Recent semiconductor chips packaged in such a power module contribute to an improvement in property, such as a reduction in loss, and have a current density that has been improved per unit area with the years. At the same time, a demand for a reduction in cost is also increased with respect to the power rating for applied devices such as an inverter. The power module is thus further required to have improved reliability upon operations at high temperature so as to enable high-power density operations.

The internal assembly of the power module is integrated by soldering. The soldering is made through the process of stacking a bonding member made of solder and a bonded member together to pass these members through a heating furnace, and then heating and melting the bonding member at a temperature exceeding a melting point of the bonding member. When a plate solder with no tackiness is used as the bonding member, a displacement of the stacked members may be caused because of shaking or the like during the sending before and after being passed through the heating furnace.

To avoid such a displacement of the stacked members, a jig having an opening capable of holding the stacked members inside the jig is used so as to make a positioning of the stacked members.

JP 2015-5559 A discloses a method of manufacturing a semiconductor device including a semiconductor element including a first solder and a second solder bonded to a rear-surface electrode by ultrasonic oscillation, and a metal plate having a recess for housing the first solder, the method including a step of positioning the semiconductor element and the metal plate while housing a part of the first solder to the recess, and a step of melting the second solder after the positioning so as to bond the semiconductor element and the metal plate to each other by soldering.

JP 2013-131735 A discloses a method of manufacturing a semiconductor device, in which a chip and a lead frame are temporarily attached to each other via a solid soldering block preliminarily provided with a projection projecting in one direction, and the projection is inserted to a solder supply hole of the lead frame to temporarily attach the chip and the lead frame to each other. Then, these members are put in a reflow furnace to melt the soldering block, followed by solidification, so as to bond the chip and the lead frame together.

JP 2018-182025 A discloses a method of manufacturing a module including a process of preparing a first solder including a plate member having a first surface and a second surface and a first projection projecting from the plate member on the first surface side, providing, on the first surface side, a first bonded member provided with a recess to which the first projection is inserted, and reflowing the first solder and the first bonded member in a state in which the first projection is inserted to the recess.

JP 2010-165764 A discloses a semiconductor device in which a surface of a thick metal block bonded to a metal foil-bonded insulated substrate is provided with a projection serving as a chip-positioning means around a bonded region of a semiconductor chip, and a projection for regulating a height of an under-chip solder is provided in the bonded region of the semiconductor chip.

The opening of the jig for positioning needs to be provided with a predetermined clearance so as not to unnecessarily press the members upon the contact when the members expand during a temperature-increasing step. The presence of the clearance, however, may cause a slight displacement of the members in the horizontal direction inside the opening, which leads the flow of the solder to be uneven on the plane surface, causing a fault such as an inclination of the members accordingly.

As described above, since the current density per unit area has been improved recent years, a reduction in area of the chip with respect to the necessary current rating is greatly enhanced. While an inclination of a large-size chip is relatively stable due to the clearance of the jig for positioning, which is determined depending on processing accuracy regardless of the width of the opening, a small-size chip tends to cause a remarkable inclination after the soldering.

The unevenness of the thickness of the bonded layer caused when the members are bonded together in the inclined state causes a thin part in the bonded layer, which leads to a decrease in resistance to thermal stress, as compared with a case in which the thickness is uniform. This further decreases the reliability of the semiconductor device such as environmental reliability and operational reliability.

### SUMMARY

In view of the foregoing issue, the present invention provides a semiconductor device with high reliability, and a method of manufacturing the same capable of avoiding a displacement of members during solder bonding so as to provide a bonded layer with a uniform thickness.

An aspect of the present invention inheres in a semiconductor device including: an insulated circuit substrate including a conductive plate provided with a recess on a main surface; a semiconductor chip arranged to be opposed to the main surface of the conductive plate; and a bonding layer interposed between the conductive plate and the semiconductor chip and provided with a projection inserted to the recess.

Another aspect of the present invention inheres in a method of manufacturing a semiconductor device, the method including: preparing an insulated circuit substrate including a conductive plate; partially fixing a plate-like bonding member onto the conductive plate so as to make a positioning of the bonding member in a horizontal direction; mounting a semiconductor chip on the bonding member; and heating and melting the bonding member so as to form a bonding layer for bonding the insulated circuit substrate and the semiconductor chip each other.

### BRIEF DESCRIPTION OF THE DRAWINGS

FIG. 1 is a plan view of a semiconductor device according to a first embodiment;

FIG. 2 is a cross-sectional view as viewed from direction A-A in FIG. 1;

FIG. 3 is a planar process view illustrating a method of manufacturing the semiconductor device according to the first embodiment;

FIG. 4 is a cross-sectional process view as viewed from direction A-A in FIG. 3;

FIG. 5 is a planar process view continued from FIG. 3 and FIG. 4 illustrating the method of manufacturing the semiconductor device according to the first embodiment;

FIG. 6 is a cross-sectional process view as viewed from direction A-A in FIG. 5;

FIG. 7 is a planar process view continued from FIG. 5 and FIG. 6 illustrating the method of manufacturing the semiconductor device according to the first embodiment;

FIG. 8 is a cross-sectional process view as viewed from direction A-A in FIG. 7;

FIG. 9 is a planar process view continued from FIG. 7 and FIG. 8 illustrating the method of manufacturing the semiconductor device according to the first embodiment;

FIG. 10 is a cross-sectional process view illustrating a method of manufacturing a semiconductor device according to a first modified example of the first embodiment;

FIG. 11 is a cross-sectional process view illustrating a method of manufacturing a semiconductor device according to a second modified example of the first embodiment;

FIG. 12 is a cross-sectional process view illustrating a method of manufacturing a semiconductor device according to a third modified example of the first embodiment;

FIG. 13 is a cross-sectional view as viewed from direction A-A in FIG. 12;

FIG. 14 is a cross-sectional process view continued from FIG. 12 and FIG. 13 illustrating the method of manufacturing the semiconductor device according to the third modified example of the first embodiment;

FIG. 15 is a plan view illustrating a semiconductor device according to a second embodiment;

FIG. 16 is a cross-sectional view as viewed from direction A-A in FIG. 15;

FIG. 17 is a planar process view illustrating a method of manufacturing the semiconductor device according to the second embodiment;

FIG. 18 is a cross-sectional process view continued from FIG. 17 illustrating the method of manufacturing the semiconductor device according to the second embodiment;

FIG. 19 is a plan view illustrating a semiconductor device according to a modified example of the second embodiment;

FIG. 20 is a planar process view illustrating a method of manufacturing the semiconductor device according to the modified example of the second embodiment;

FIG. 21 is a plan view illustrating a semiconductor device according to a third embodiment;

FIG. 22 is a cross-sectional view as viewed from direction A-A in FIG. 21;

FIG. 23 is a planar process view illustrating a method of manufacturing the semiconductor device according to the third embodiment;

FIG. 24 is a planar process view continued from FIG. 23 illustrating the method of manufacturing the semiconductor device according to the third embodiment;

FIG. 25 is a cross-sectional view as viewed from direction A-A in FIG. 24;

FIG. 26 is a planar process view continued from FIG. 24 and FIG. 25 illustrating the method of manufacturing the semiconductor device according to the third embodiment;

FIG. 27 is a cross-sectional process view illustrating a method of manufacturing a semiconductor device according to a first modified example of the third embodiment; and

FIG. 28 is a cross-sectional process view illustrating a method of manufacturing a semiconductor device according to a second modified example of the third embodiment.

### DETAILED DESCRIPTION

With reference to the Drawings, embodiments of the present invention will be described below.

In the Drawings, the same or similar elements are indicated by the same or similar reference numerals. The Drawings are schematic, and it should be noted that the relationship between thickness and planer dimensions, the thickness proportion of each layer, and the like are different from real ones. Moreover, in some drawings, portions are illustrated with different dimensional relationships and proportions.

The embodiments described below merely illustrate schematically devices and methods for specifying and giving shapes to the technical idea of the present invention, and the span of the technical idea is not limited to materials, shapes, structures, and relative positions of elements described herein.

Further, definitions of directions such as an up-and-down direction in the following description are merely definitions for convenience of understanding, and are not intended to limit the technical ideas of the present invention. For example, as a matter of course, when the subject is observed while being rotated by 90°, the subject is understood by converting the up-and-down direction into the right-and-left direction. When the subject is observed while being rotated by 180°, the subject is understood by inverting the up-and-down direction.

### First Embodiment

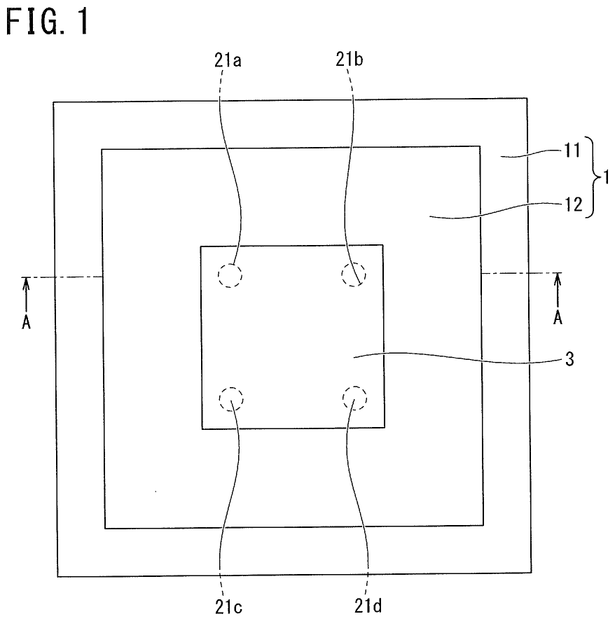

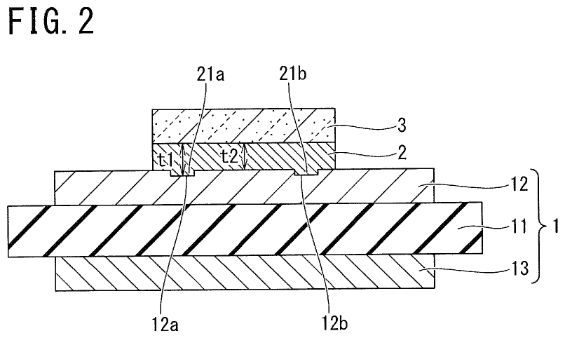

FIG. 1 is a plan view of a semiconductor device according to a first embodiment, and FIG. 2 is a cross-sectional view as viewed from direction A-A in FIG. 1. As illustrated in FIG. 1 and FIG. 2, the semiconductor device according to the first embodiment is a power module including an insulated circuit substrate (a wired plate) 1, a semiconductor chip (a power semiconductor chip) 3 arranged to be opposed to the main surface (the top surface) of the insulated circuit substrate 1, and a bonding layer 2 interposed between the insulated circuit substrate 1 and the semiconductor chip 3.

Although not illustrated in FIG. 1 or FIG. 2, a metal base or a radiation fin may be provided on the bottom surface side of the insulated circuit substrate 1. The insulated circuit substrate 1 and the semiconductor chip 3 may be housed in an external case made from resin. The external case may be filled with sealing resin so as to seal the insulated circuit substrate 1 and the semiconductor chip 3 in the external case.

The insulated circuit substrate 1 is a direct copper bonded (DCB) substrate or an active metal brazed (AMB) substrate, for example. The insulated circuit substrate 1 includes an insulating plate 11, a conductive plate (a circuit plate) 12 deposited on the top surface of the insulating plate 11, and a conductive plate (a radiation plate) 13 deposited on the bottom surface of the insulating plate 11. As illustrated in FIG. 2, the main surface (the top surface) of the conductive plate 12 is provided with recesses 12a and 12b.

The insulating plate 11 is a ceramic substrate made from aluminum oxide (Al₂O₃), aluminum nitride (AlN), or silicon nitride (Si₃N₄), or a resin insulating plate using polymer material, for example. The conductive plate 12 and the conductive plate 13 are each conductive foil made from copper (Cu) or aluminum (Al), for example.

The semiconductor chip 3 is arranged to be opposed to the main surface (the top surface) of the conductive plate 12. A bottom-surface electrode made from gold (Au) of the semiconductor chip 3 is bonded to the conductive plate 12 via the bonding layer 2. The semiconductor chip 3 to be used may be an insulated gate bipolar transistor (IGBT), a field-effect transistor (FET), a static induction (SI) thyristor, a gate turn-off (GTO) thyristor, or a freewheeling diode (FWD), for example. The semiconductor chip 3 may be either a unipolar device or a bipolar device. The semiconductor chip 3 may be a silicon (Si) substrate, or may be a chemical semiconductor substrate of a wide-bandgap semiconductor made from silicon carbide (SiC), gallium nitride (GaN), gallium arsenide (GaAs), gallium oxide (Ga₂O₃), or diamond (C), for example.

While FIG. 1 and FIG. 2 illustrate the case of including the single semiconductor chip 3, the number of the semiconductor chips can be determined as appropriate depending on a current capacity of the power module, for example, and the power module may include two or more semiconductor chips. When including two or more semiconductor chips, the power module may include either the same kind of semiconductor chips or different kinds of semiconductor chips. As illustrated in FIG. 1, the semiconductor chip 3 has a rectangular planar pattern. While the semiconductor chip 3 is illustrated herein with a case of having a size of 3 square millimeters or greater and 20 square millimeters or smaller, for example, the size is not limited to this case.

As illustrated in FIG. 2, the bonding layer 2 is interposed between the conductive plate 12 of the insulated circuit substrate 1 and the semiconductor chip 3 so as to bond (fix) the conductive plate 12 and the semiconductor chip 3 to each other. The bonding layer 2 to be used can be tin-antimony-based (SnSb) or tin-silver-based (SnAg) solder, for example.

The bottom surface of the bonding layer 2 is provided with projections 21a and 21b. The projections 21a and 21b are inserted to the recesses 12a and 12b of the conductive plate 12. A thickness t1 of the bonding layer 2 at a position provided with the projections 21a and 21b is greater than a thickness t2 of the bonding layer 2 at a position not provided with the projections 21a and 21b. The projections 21a and 21b are illustrated with a case of having a columnar shape, for example, but the shape is not necessarily limited to this case. The projections 21a and 21b may be formed into a circular cone, a polygonal column, or a polygonal pyramid, for example. The shape of the recesses 12a and 12b of the conductive plate 12 can also be any shape to which the projections 21a and 21b can be inserted.

The bonding layer 2 is illustrated with a case of having a rectangular planar pattern, but is not necessarily limited to this case. The bonding layer 2 may have a circular planar pattern, for example. The outer edge of the bonding layer 2 is herein configured to conform to the outer edge of the semiconductor chip 3 illustrated in FIG. 1. The outer edge of the bonding layer 2 may be located either on the outside or on the inside of the outer edge of the semiconductor chip 3. Namely, the size of the bonding layer 2 may be either greater than or smaller than the size of the semiconductor chip 3.

FIG. 1 schematically indicates the projections 21a to 21d by the broken lines provided on the bottom surface of the bonding layer 2. The projections 21a to 21d are provided at the positions close to the four corners of the rectangular shape on the inside of the outer circumference of the planar pattern of the bonding layer 2. Although not illustrated, the conductive plate 12 is further provided with recesses corresponding to the respective projections 21c and 21d of the bonding layer 2 so that the projections 21c and 21d of the bonding layer 2 are inserted to the corresponding recesses of the conductive plate 12.

The arrangement positions of the projections 21a to 21d of the bonding layer 2 may be determined as appropriate. In addition, the bonding layer 2 only needs to be provided with at least one projection, or alternatively, may be provided with two, three, or five or greater of projections.

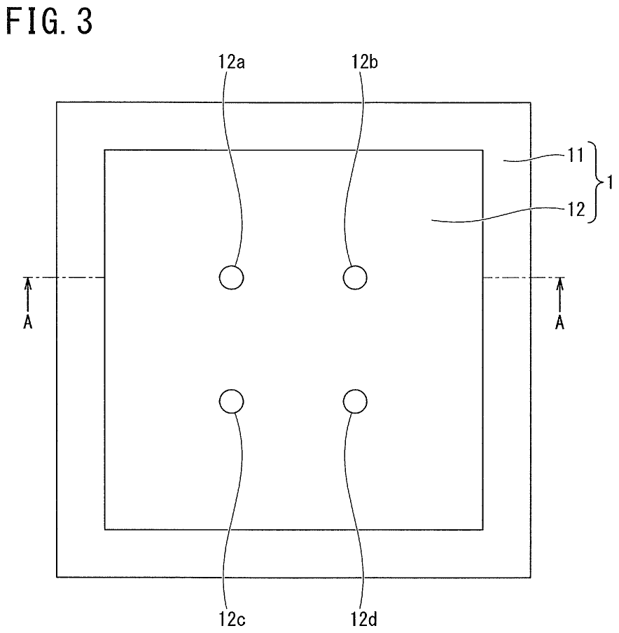

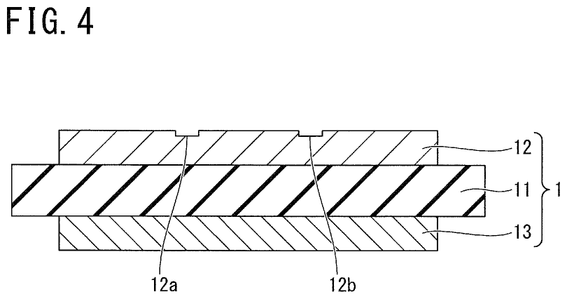

A method of manufacturing (a method of assembling) the semiconductor device according to the first embodiment is described below. As illustrated in FIG. 3 and FIG. 4, the insulated circuit substrate 1 including the conductive plate 12 provided with the recesses 12a to 12d is prepared first. The recesses 12a to 12d of the conductive plate 12 can be formed by cutting processing by use of a tool such as a drill or laser irradiation, for example.

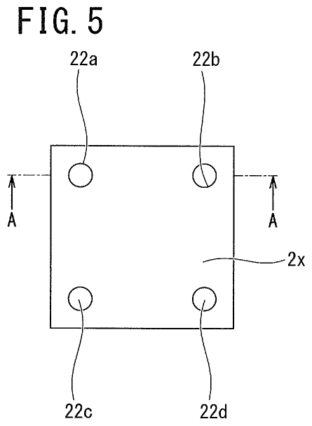

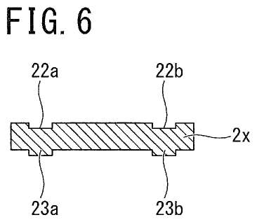

A bonding member (also referred to as “preform solder”, “plate solder”, or “solder pellet”) 2x made of solid solder formed into a plate shape is also prepared, as illustrated in FIG. 5 and FIG. 6. The top surface of the bonding member 2x is provided with recesses 22a to 22d, and the bottom surface of the bonding member 2x is provided with projections 23a and 23b. The recesses 22a and 22b are formed at positions overlapping with the projections 23a and 23b. The bottom surface of the bonding member 2x is also provided with projections (not illustrated) at positions overlapping with the recesses 22c and 22d. The recesses 22a to 22d and the projections 23a and 23b can be formed such that the bonding member 2x having the flat top and bottom surfaces subjected to rolling processing is subjected to plastic deformation by use of a metal die, for example. The top surface of the bonding member 2x may be flat without being provided with the recesses 22a to 22d, which is determined depending on the method of processing the bonding member 2x.

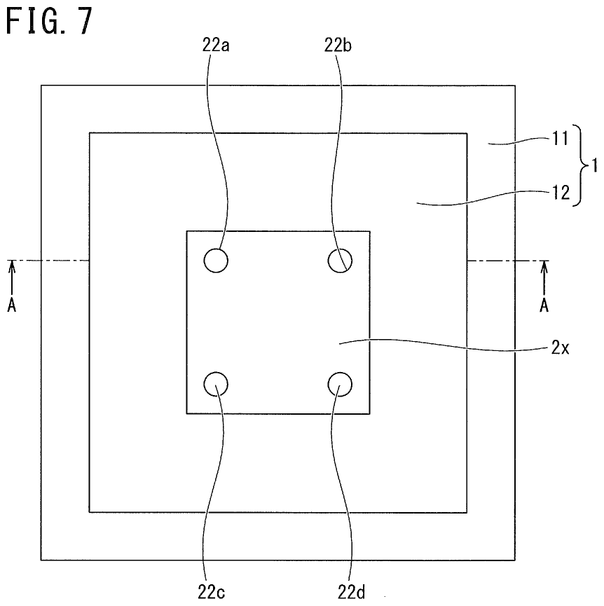

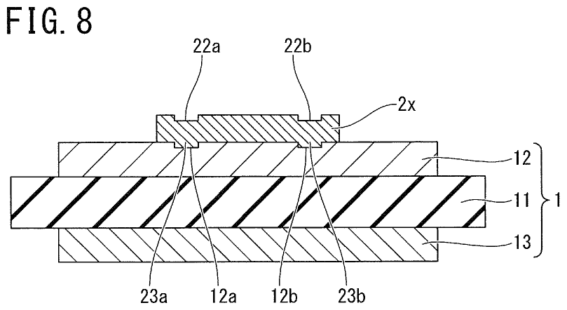

Next, as illustrated in FIG. 7 and FIG. 8, the bonding member 2x having the top surface provided with the recesses 22a to 22d and the bottom surface provided with the projections 23a and 23b is mounted on the insulated circuit substrate 1 including the conductive plate 12 provided with the recesses 12a and 12b. The projections 23a and 23b provided on the bottom surface of the bonding member 2x are inserted (fitted) to be fixed (locked) to the recesses 12a and 12b of the conductive plate 12. Similarly, although not illustrated in the drawings, the projections provided on the bottom surface of the bonding member 2x at the positions overlapping with the recesses 22c and 22d of the bonding member 2x are also inserted to be fixed to the recesses 12c and 12d. These insertion and fixation described above lead the bonding member 2x to be positioned in the horizontal direction. The bonding member 2x is held in the horizontal direction due to the fitted state between the projections 23a and 23b on the bottom surface of the bonding member 2x and the recesses 12a and 12b of the conductive plate 12, so as to be uniformly brought into contact with the top surface of the conductive plate 12.

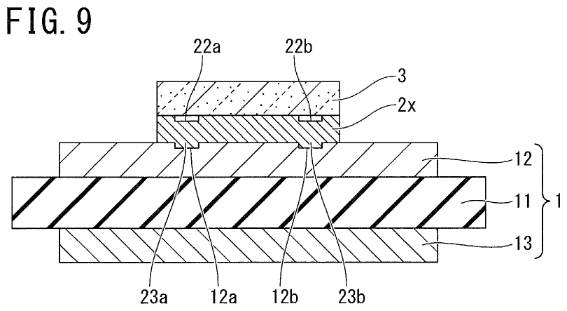

Next, as illustrated in FIG. 9, the semiconductor chip 3 is mounted to be stacked on the bonding member 2x. The bonding member 2x is positioned in the horizontal direction and is thus uniformly brought into contact with (closely attached to) the top surface of the conductive plate 12, so as to avoid or decrease an inclination of the held surface of the semiconductor chip 3 mounted on the bonding member 2x.

Next, the stacked body of the insulated circuit substrate 1, the bonding member 2x, and the semiconductor chip 3 is sent to a heating furnace. The insulated circuit substrate 1, the bonding member 2x, and the semiconductor chip 3 in this case can easily keep the state of being in uniform surface contact with each other, regardless of whether an influence such as shaking caused during the sending is exerted. The bonding member 2x is heated and melted in the heating furnace so as to form the bonding layer 2 for bonding the insulated circuit substrate 1 and the semiconductor chip 3 to each other. The insulated circuit substrate 1 and the semiconductor chip 3 are then housed in the external case to be filled with sealing resin, and a radiation base or a radiation fin is attached on the bottom surface side of the insulated circuit substrate 1, so as to complete the semiconductor device according to the first embodiment.

The method of manufacturing the semiconductor device according to the first embodiment, which inserts the projections 23a and 23b provided on the bottom surface of the bonding member 2x to the recesses 12a and 12b provided on the conductive plate 12, can make a positioning of the bonding member 2x mounted on the top surface of the insulated circuit substrate 1 on the horizontal plane. This can avoid a displacement of the bonding member 2x deposited on the bottom surface of the semiconductor chip 3, regardless of whether an influence such as shaking caused during the sending to the heating furnace is exerted, so as to avoid a displacement of the semiconductor chip 3 accordingly.

When a positioning jig for holding the members with a frame body is used, a clearance needs to be provided between the bonding member 2x and the semiconductor chip 3 and the frame body, and even a slight individual displacement of the bonding member 2x or the semiconductor chip 3 thus could cause an inclination of the bonding member 2x and the semiconductor chip 3. In contrast, the method of manufacturing the semiconductor device according to the first embodiment can avoid a cause of a slight individual displacement of the bonding member 2x or the semiconductor chip 3, so as to keep the uniform contact state between the bonding member 2x and the semiconductor chip 3. When the temperature in the heating furnace increases, the melting of the solder and the flow toward the bonded member start equally on the plane. This can prevent an unstable state of the semiconductor chip 3 even after the solder is completely melted, so as to allow the conductive plate 12 and the semiconductor chip 3 interposing the bonding member 2x to be bonded together while keeping the horizontal state. The bonding layer 2 having a uniform thickness thus can be provided.

The uniform thickness of the bonding layer 2 to which a load is applied during the high-temperature operation can avoid a cause of a thin and weak part in the bonding layer 2 derived from an uneven thickness. The uniform thickness thus enables the bonding layer 2 to enhance reliability of long duration, so as to improve the reliability of the semiconductor device accordingly.

In addition, since the positioning function of a carbon jig and the like can be limited to the positioning between the lead frame and the substrate in a packaged configuration in which an upper-side structure such as lead frame wiring is complicated, the number of processing points by use of the jig and the like can be decreased. Further, since the inclination of the semiconductor chip 3 and the lead frame can also be avoided, the thickness of the bonding layer between the insulated circuit substrate 1 and the semiconductor chip 3 and the thickness of the bonding layer between the semiconductor chip 3 and the lead frame can be uniformly fixed, so as to enhance the improvement of the reliability.

### First Modified Example of First Embodiment

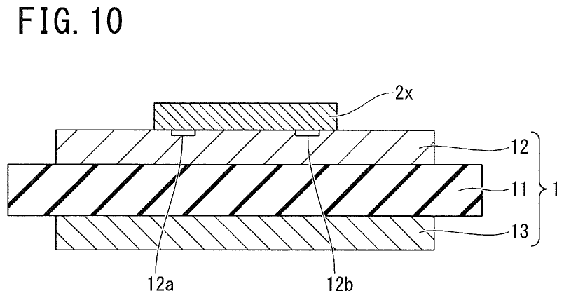

The method of manufacturing the semiconductor device according to the first embodiment is illustrated above with the case of mounting the bonding member 2x having the bottom surface provided with the projections 23a and 23b on the insulated circuit substrate 1 including the conductive plate 12 provided with the recesses 12a and 12b so as to insert the projections 23a and 23b of the bonding member 2x to the recesses 12a and 12b of the conductive plate 12, as illustrated in FIG. 7 and FIG. 8. Alternatively, as illustrated in FIG. 10, the bonding member 2x having flat top and bottom surfaces may be mounted on the insulated circuit substrate 1 including the conductive plate 12 provided with the recesses 12a and 12b.

In such a case, the bonding member 2x is locally pressed with a tool, for example, in the state illustrated in FIG. 10 to form the projections 23a and 23b on the bottom surface of the bonding member 2x, as illustrated in FIG. 7 and FIG. 8, so as to insert the projections 23a and 23b to the recesses 12a and 12b of the conductive plate 12. This can make a positioning of the bonding member 2x in the horizontal direction. The other steps are the same as those in the method of manufacturing the semiconductor device according to the first embodiment, and overlapping explanations are not repeated below.

### Second Modified Example of First Embodiment

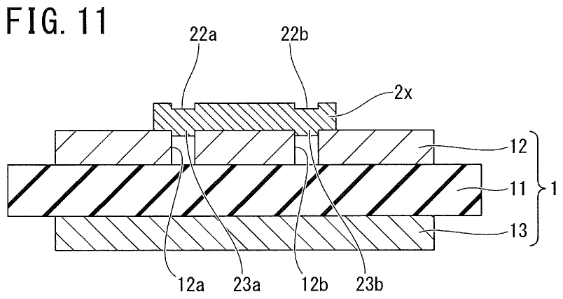

The method of manufacturing the semiconductor device according to the first embodiment is illustrated above with the case of mounting the bonding member 2x having the bottom surface provided with the projections 23a and 23b on the insulated circuit substrate 1 including the conductive plate 12 provided with the recesses 12a and 12b formed into a predetermined depth in the conductive plate 12 so as to insert the projections 23a and 23b of the bonding member 2x to the recesses 12a and 12b of the conductive plate 12, as illustrated in FIG. 8. Alternatively, the recesses 12a and 12b of the conductive plate 12 may penetrate the conductive plate 12 so as to expose a part of the top surface of the insulating plate 11, as illustrated in FIG. 11.

This configuration also leads the projections 21a and 21b of the bonding member 2x to be inserted to the recesses 12a and 12b of the conductive plate 12, so as to make a positioning of the bonding member 2x in the horizontal direction. The other steps are the same as those in the method of manufacturing the semiconductor device according to the first embodiment, and overlapping explanations are not repeated below.

### Third Modified Example of First Embodiment

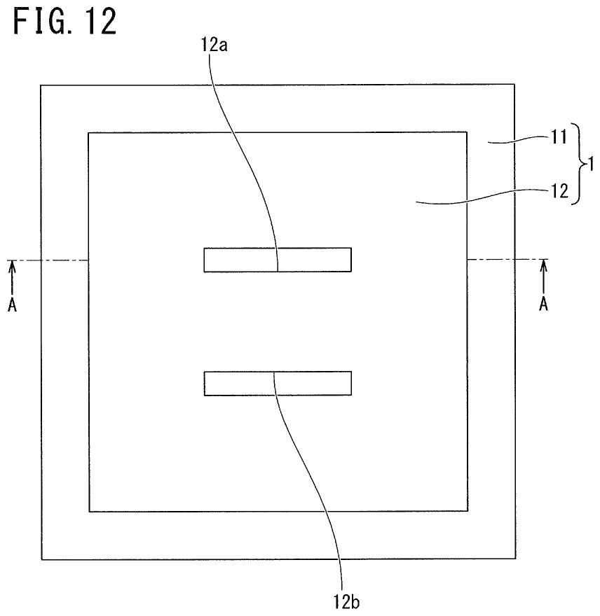

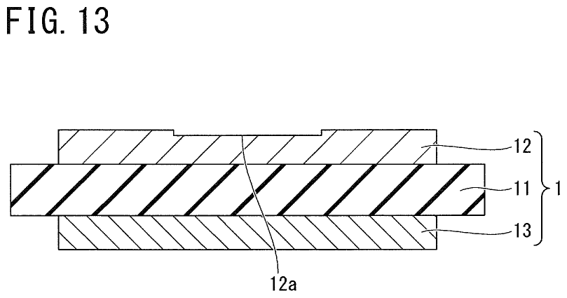

The method of manufacturing the semiconductor device according to the first embodiment is illustrated above with the case of forming the recesses 12a to 12d into a dotted state (a spot state) in the conductive plate 12 of the insulated circuit substrate 1, as illustrated in FIG. 3 and FIG. 4. The planar pattern of the recesses 12a to 12d is not necessarily limited to the dotted state (the spot state). For example, as illustrated in FIG. 12 and FIG. 13, the conductive plate 12 may be provided with the recesses 12a and 12b having a groove-like shape. The recesses 12a and 12b have a striped planar pattern extending parallel to each other, for example.

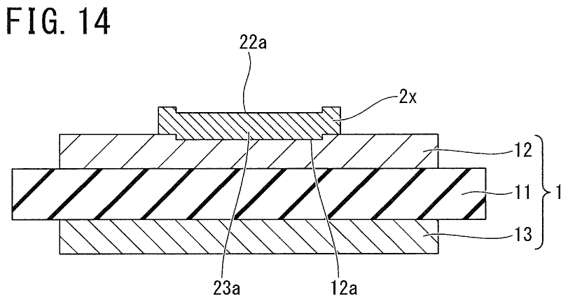

In this case, as illustrated in FIG. 14, the bonding member 2x is provided with a striped projection 23a conforming to the recesses 12a. Although not illustrated in the drawing, the bonding member 2x is also provided with a striped projection conforming to the recesses 12b. The bonding member 2x is mounted on the insulated circuit substrate 1 to insert the projection 21a of the bonding member 2x to the recess 12a of the conductive plate 12, so as to make a positioning of the bonding member 2x in the horizontal direction. The other steps are the same as those in the method of manufacturing the semiconductor device according to the first embodiment, and overlapping explanations are not repeated below.

### Second Embodiment

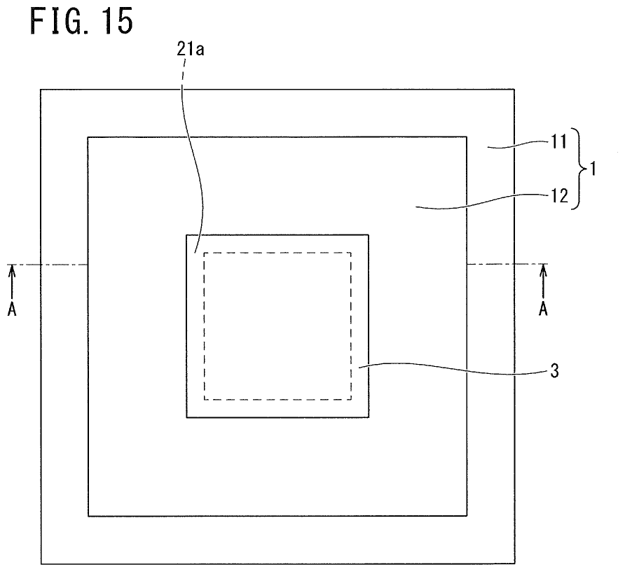

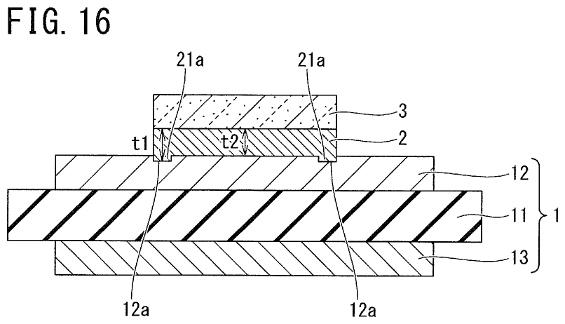

A semiconductor device according to a second embodiment has a configuration common to that of the semiconductor device according to the first embodiment in including the insulated circuit substrate 1, the semiconductor chip 3 arranged to be opposed to the top surface of the insulated circuit substrate 1, and the bonding layer 2 interposed between the insulated circuit substrate 1 and the semiconductor chip 3, as illustrated in FIG. 15 and FIG. 16. The semiconductor device according to the second embodiment differs from the semiconductor device according to the first embodiment in that the projection 21a of the bonding layer 2 is provided along the outer circumference of the bonding layer 2.

The thickness t1 of the bonding layer 2 at the outer circumference provided with the projection 21a is greater than the thickness t2 of the bonding layer 2 at the position not provided with the projection 21a. FIG. 15 schematically indicates the planar pattern of the projection 21a of the bonding layer 2 by the broken line. The projection 21a of the bonding layer 2 has a ring-like (frame-like) planar pattern. The recess 12a provided in the conductive plate 12 of the insulated circuit substrate 1 has a ring-like (frame-like) planar pattern at a position corresponding to the projection 21a of the bonding layer 2. The projection 21a of the bonding layer 2 is inserted to the recess 12a of the conductive plate 12. The other configurations of the semiconductor device according to the second embodiment are the same as those of the semiconductor device according to the first embodiment, and overlapping explanations are not repeated below.

While configuration of the semiconductor device according to the second embodiment tends to cause a stress to concentrate at the outer circumference of the bonding layer 2 more than the middle part, which may easily cause cracks, the provision of the projection 21a along the outer circumference of the bonding layer 2 increases the thickness t1 at the outer circumference of the bonding layer 2 more than the thickness t2 in the middle part, so as to avoid or stop an advance of cracks caused. This can enhance the environmental reliability of long duration.

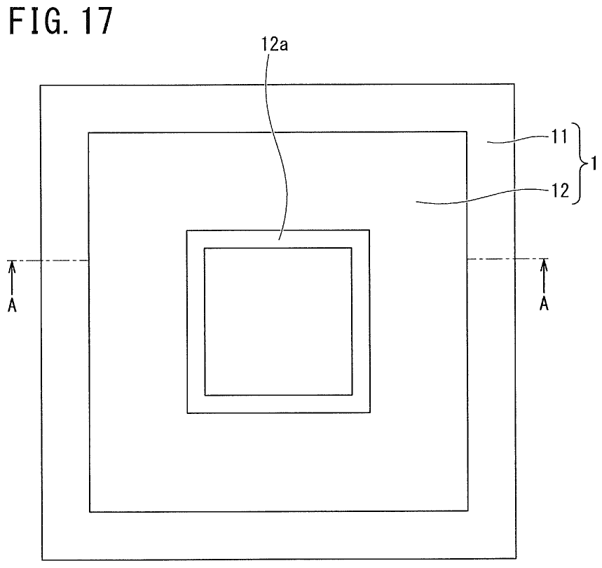

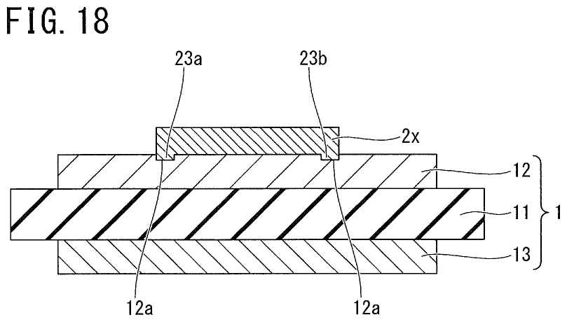

A method of manufacturing the semiconductor device according to the second embodiment is described below. The method of manufacturing the semiconductor device according to the second embodiment forms the ring-like (frame-like) recess 12a on the conductive plate 12 of the insulated circuit substrate 1 by cutting processing with a tool, as illustrated in FIG. 17. The manufacturing method then mounts the bonding member 2x having the bottom surface provided with the ring-like (frame-like) projection 23a corresponding to the recess 12a on the insulated circuit substrate 1, as illustrated in FIG. 18. The projection 21a of the bonding member 2x is at the same time inserted to the recess 12a of the conductive plate 12, so as to make a positioning of the bonding member 2x in the horizontal direction. The bonding member 2x may be provided with a recess on the top surface at a position overlapping with the projection 23a, depending on the method of processing the bonding member 2x. The other steps of the method of manufacturing the semiconductor device according to the second embodiment are the same as those of the method of manufacturing the semiconductor device according to the first embodiment, and overlapping explanations are not repeated below.

The method of manufacturing the semiconductor device according to the second embodiment, which inserts the projection 21a of the bonding member 2x to the recess 12a of the conductive plate 12, can make a positioning of the bonding member 2x in the horizontal direction, so as to avoid a displacement of the bonding member 2x and the semiconductor chip 3 regardless of whether an influence such as shaking caused during the sending is exerted.

### Modified Example of Second Embodiment

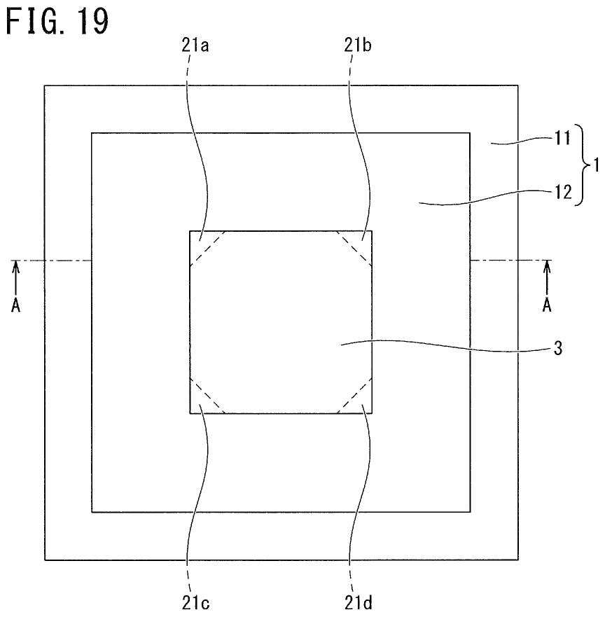

The semiconductor device according to the second embodiment is illustrated above with the case of providing the projection 21a of the bonding layer 2 into the ring-like (frame-like) shape at the outer circumference of the bonding layer 2, as schematically indicated by the broken line in FIG. 15. Alternatively, as schematically indicated by the broken line in FIG. 19, the bonding layer 2 may be provided with the projections 21a to 21d at the four corners at the outer circumference of the rectangular shape that is the planar pattern of the bonding layer 2.

The modified example of the second embodiment, which provides the projections 21a to 21d at the corners of the outer circumference of the bonding layer 2, can relatively increase the thickness at the corners at the outer circumference of the bonding layer 2, so as to avoid or stop an advance of cracks that tend to be caused at the corners at the outer circumference of the bonding layer 2. This can enhance the environmental reliability of long duration.

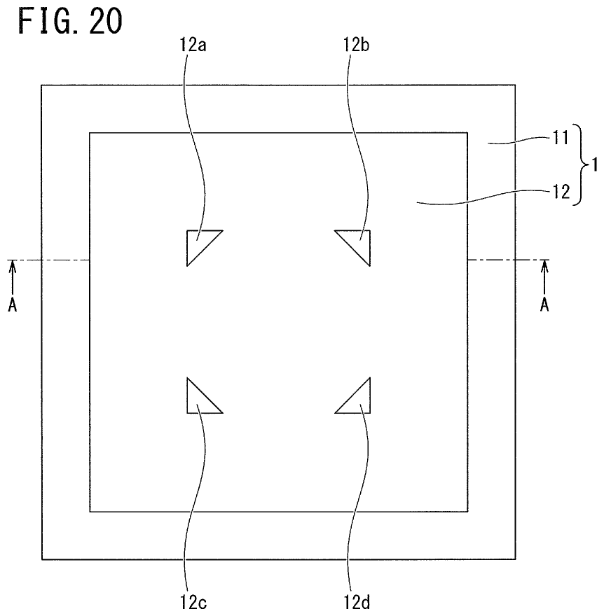

A method of manufacturing the semiconductor device according to the modified example of the second embodiment, as illustrated in FIG. 20, forms the recesses 12a to 12d at the positions to which the corresponding projections 21a to 21d of the bonding layer 2 illustrated in FIG. 19 are inserted in the conductive plate 12 of the insulated circuit substrate 1. The projections 21a to 21d of the bonding member in a solid state before the bonding layer 2 illustrated in FIG. 19 is heated and melted are inserted to the recesses 12a to 12d of the conductive plate 12, so as to make a positioning of the bonding member 2x in the horizontal direction.

### Third Embodiment

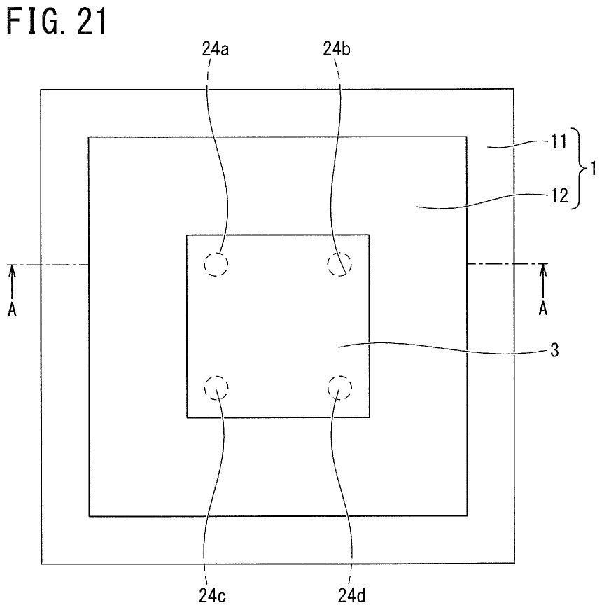

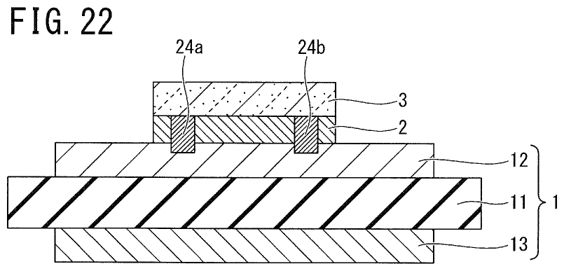

A semiconductor device according to a third embodiment has a configuration common to that of the semiconductor device according to the first embodiment in including the insulated circuit substrate 1, the semiconductor chip 3 arranged to be opposed to the top surface of the insulated circuit substrate 1, and the bonding layer 2 interposed between the insulated circuit substrate 1 and the semiconductor chip 3, as illustrated in FIG. 21 and FIG. 22. The semiconductor device according to the third embodiment differs from the semiconductor device according to the first embodiment in providing the bonding layer 2 with columnar-shaped partial melting parts (alloy layers) 24a to 24d, which serve as projections provided on the bottom surface of the bonding layer 2.

The partial melting parts 24a to 24d can be formed such that a bonding member in a solid state before the bonding layer 2 is heated and melted is subjected to laser welding (laser spot welding) during the manufacture of the semiconductor device according to the third embodiment. The partial melting parts 24a to 24d are the alloy layers in which the material of the bonding layer 2 and the material of the conductive plate 12 are melted and solidified. When the material of the conductive plate 12 is copper (Cu), for example, the partial melting parts 24a to 24d serve as regions containing Cu with a higher concentration than the bonding layer 2.

While FIG. 22 illustrates the case in which the partial melting parts 24a to 24d penetrate the bonding layer 2 so that the upper ends of the partial melting parts 24a to 24d conform to the top surface of the bonding layer 2, the third embodiment is not limited to this case. For example, the upper ends of the partial melting parts 24a to 24d may be located inside the bonding layer 2 without penetrating the bonding layer 2. The lower ends of the partial melting parts 24a to 24d project from the bottom surface of the bonding layer 2 to serve as projections. The conductive plate 12 is provided with recesses at the positions corresponding to the projections at the lower ends of the partial melting parts 24a to 24d.

FIG. 21 schematically indicates the partial melting parts 24a to 24d by the broken lines. The partial melting parts 24a to 24d are provided at the four corners of the rectangular shape that is the planar pattern of the bonding layer 2. The partial melting parts 24a to 24d have the planar pattern in a dotted state (a spot state). While the third embodiment is illustrated with the case of providing the four partial melting parts 24a to 24d, the number of the partial melting parts to be provided may be one to three or five or greater. The arrangement positions of the partial melting parts 24a to 24d may also be determined as appropriate. The other configurations of the semiconductor device according to the third embodiment are the same as those of the semiconductor device according to the first embodiment, and overlapping explanations are not repeated below.

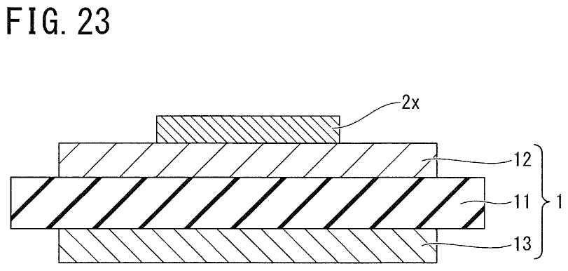

A method of manufacturing the semiconductor device according to the third embodiment is described below. The method of manufacturing the semiconductor device according to the third embodiment prepares the insulated circuit substrate 1 including the conductive plate 12 having the flat top surface, and also prepares the bonding member 2x having the flat top and bottom surfaces, as illustrated in FIG. 23. The bonding member 2x is then mounted on the conductive plate 12 of the insulated circuit substrate 1.

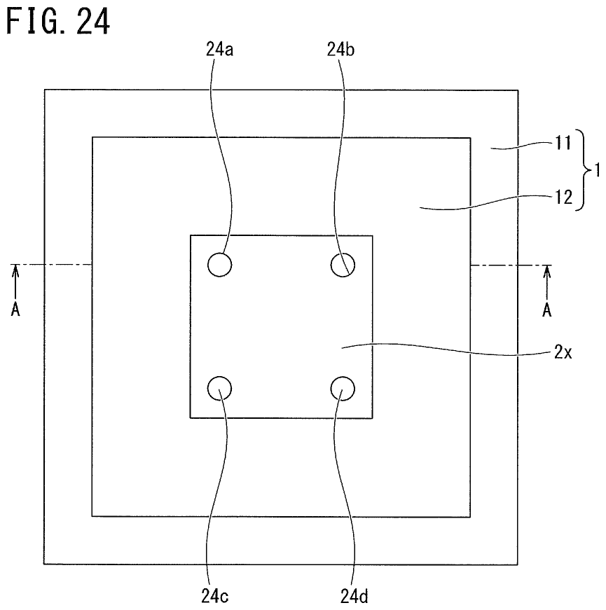

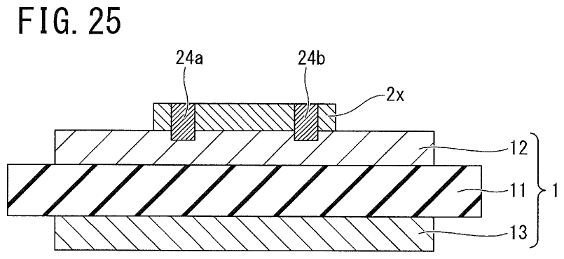

Next, as illustrated in FIG. 24 and FIG. 25, a part of the bonding member 2x and a part of the conductive plate 12 are melted by laser welding so as to form the partial melting parts (nuggets) 24a to 24d. The laser welding is made such that heat is applied to the inside from the top surface of the bonding member 2x by spot thermal spraying. This allows the bonding member 2x and the conductive plate 12 to be partially strongly bonded to each other, so as to make a positioning of the bonding member 2x in the horizontal direction.

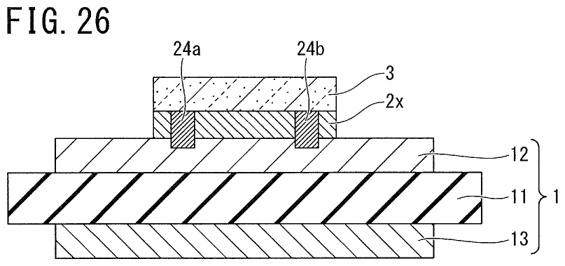

Next, as illustrated in FIG. 26, the semiconductor chip 3 is mounted on the bonding member 2x. The stacked body of the insulated circuit substrate 1, the bonding member 2x, and the semiconductor chip 3 is then sent to a heating furnace. The bonding member 2x is heated and melted in the heating furnace so as to form the bonding layer 2 for bonding the insulated circuit substrate 1 and the semiconductor chip 3 to each other. The other steps of the method of manufacturing the semiconductor device according to the third embodiment are the same as those of the method of manufacturing the semiconductor device according to the first embodiment, and overlapping explanations are not repeated below.

The method of manufacturing the semiconductor device according to the third embodiment, which forms the partial melting parts 24a to 24d in the bonding member 2x by the laser welding, can avoid a displacement of the bonding member 2x and the semiconductor chip 3 caused by shaking during the sending of the stacked body of the insulated circuit substrate 1, the bonding member 2x, and the semiconductor chip 3 to the heating furnace. In addition, a displacement of the bonding member 2x and the semiconductor chip 3 can also be avoided due to the partial melting parts 24a to 24d during the solder bonding in association with the entire welding of the bonding member 2 in the heating furnace after the sending to the heating furnace.

The laser welding may be executed after the bonding member 2x having the bottom surface provided with the projections 23a and 23b is mounted on the insulated circuit substrate 1 including the conductive plate 12 provided with the recesses 12a and 12b, and the projections 23a and 23b of the bonding member 2x are inserted to the recesses 12a and 12b so as to fix the bonding member 2x to the insulated circuit substrate 1, as illustrated in FIG. 8.

### First Modified Example of Third Embodiment

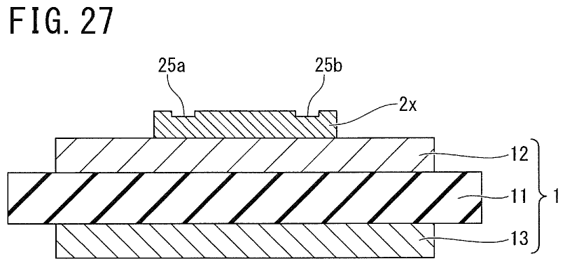

The method of manufacturing the semiconductor device according to the third embodiment is illustrated above with the case of executing the laser welding after mounting the bonding member 2x having the flat top and bottom surfaces on the insulated circuit substrate 1, as illustrated in FIG. 23. Alternatively, as illustrated in FIG. 27, recesses 25a and 25b may be formed, before the laser welding, at positions on the top surface of the bonding member 2x to which heat is applied by the laser welding. The recesses 25a and 25b can be formed such that the bonding member 2x having the flat top and bottom surfaces is subjected to plastic processing or stamping processing.

The method of manufacturing the semiconductor device according to the first modified example of the third embodiment, which provides the recesses 25a and 25b on the top surface of the bonding member 2x, can enhance light-condensing performance. This can decrease the level of power of the laser for forming the partial melting parts 24a to 24d, so as to improve the laser irradiation efficiency.

### Second Modified Example of Third Embodiment

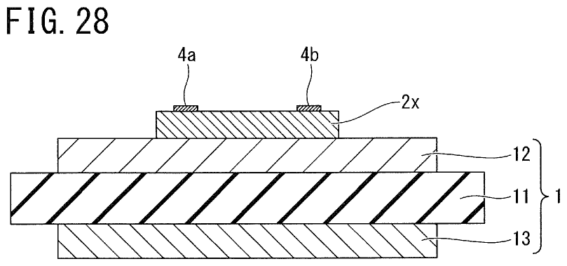

The method of manufacturing the semiconductor device according to the third embodiment is illustrated above with the case of executing the laser welding after mounting the bonding member 2x having the flat top and bottom surfaces on the insulated circuit substrate 1, as illustrated in FIG. 23. Alternatively, as illustrated in FIG. 28, metal layers 4a and 4b may be formed, before the laser welding, at positions on the top surface of the bonding member 2x to which heat is applied by the laser welding. Examples of material used for the metal layers 4a and 4b include nickel (Ni), palladium (Pd), platinum (Pt), and silver (Ag). The metal layers 4a and 4b may be formed such that a metal layer is deposited on the entire top surface of the bonding member 2x by sputtering or vapor deposition, for example, and a part of the metal layer is then selectively removed by use of a mask.

The method of manufacturing the semiconductor device according to the second modified example of the third embodiment, which locally forms the metal layers 4a and 4b on the top surface of the bonding member 2x, can improve the heat-application efficiency during the laser welding, so as to enhance the laser irradiation efficiency.

### Other Embodiments

As described above, the invention has been described according to the first to third embodiments, but it should not be understood that the description and drawings implementing a portion of this disclosure limit the invention. Various alternative embodiments of the present invention, examples, and operational techniques will be apparent to those skilled in the art from this disclosure.

For example, the configurations disclosed in the first to third embodiments may be combined as appropriate within a range that does not contradict with the scope of the respective embodiments. As described above, the invention includes various embodiments of the present invention and the like not described herein. Therefore, the scope of the present invention is defined only by the technical features specifying the present invention, which are prescribed by claims, the words and terms in the claims shall be reasonably construed from the subject matters recited in the present Specification.

What is claimed is:

1. A semiconductor device comprising:
an insulated circuit substrate including a conductive plate provided with a recess on a main surface;
a semiconductor chip arranged to be opposed to the main surface of the conductive plate; and
a bonding layer interposed between the conductive plate and the semiconductor chip and provided with a projection inserted to the recess.

2. The semiconductor device of claim 1, wherein the projection is provided on an inner side of an outer circumference of the bonding layer.

3. The semiconductor device of claim 1, wherein the projection is provided at an outer circumference of the bonding layer.

4. The semiconductor device of claim 1, wherein the projection is a part of the bonding layer.

5. The semiconductor device of claim 1, wherein the projection is a partial melting part of the bonding layer and the conductive plate.

6. A method of manufacturing a semiconductor device, the method comprising:
preparing an insulated circuit substrate including a conductive plate;
partially fixing a plate-like bonding member onto the conductive plate so as to make a positioning of the bonding member in a horizontal direction;
mounting a semiconductor chip on the bonding member; and
heating and melting the bonding member so as to form a bonding layer for bonding the insulated circuit substrate and the semiconductor chip each other.

7. The method of manufacturing the semiconductor device of claim 6, wherein the positioning of the bonding member in the horizontal direction is made by inserting a projection provided on the bonding member to a recess provided on the conductive plate.

8. The method of manufacturing the semiconductor device of claim 6, wherein the positioning of the bonding member in the horizontal direction is made by bonding a part of the conductive plate and a part of the bonding member to each other by laser welding.

9. The method of manufacturing the semiconductor device of claim 8, further comprising, before the laser welding, forming a recess at a position on a top surface of the bonding member to which heat is applied by the laser welding.

10. The method of manufacturing the semiconductor device of claim 8, further comprising, before the laser welding, selectively forming a metal layer at a position on a top surface of the bonding member to which heat is applied by the laser welding.
